(19) United States
(12) Patent Application Publication
(10) Pub. No.: US 2026/0033251 A1
(43) Pub. Date: Jan. 29, 2026

(54) PHASE CHANGE MATERIAL SWITCH

(71) Applicants: Commissariat à l'Énergie Atomique et aux Énergies Alternatives, Paris (FR); Universite Grenoble Alpes, Saint Martin D'Heres (FR); Institut Polytechnique de Grenoble, Grenoble Cedex 1 (FR)

(72) Inventors: Ayoub Naoui, Grenoble (FR); Ismaël Charlet, Grenoble (FR)

(73) Assignees: Commissariat à l'Énergie Atomique et aux Énergies Alternatives, Paris (FR); Universite Grenoble Alpes, Saint Martin D'Heres (FR); Institut Polytechnique de Grenoble, Grenoble Cedex 1 (FR)

(21) Appl. No.: 19/277,827

(22) Filed: Jul. 23, 2025

(30) Foreign Application Priority Data
Jul. 26, 2024 (FR) FR2408331

(51) Int. Cl. H10N 70/20; H10N 70/00

(52) U.S. Cl. CPC H10N 70/231; H10N 70/257; H10N 70/8828; H10N 70/8833

(57) ABSTRACT

A switch based on a phase-change material including: a region of said phase-change material coupling first and second conduction electrodes of the switch; a waveguide located vertically in line with the region of said phase-change material and including a central region of a first material having a first refractive index surrounded by a peripheral region of a second material having a second refractive index lower than the first refractive index; and a region of a third material having a third refractive index lower than the second refractive index and located in the peripheral region of the waveguide vertically in line with a first face of the central region of the waveguide opposite the region of said phase-change material.

### CROSS REFERENCE TO RELATED APPLICATIONS

This application claims priority to French application number FR2408331, filed Jul. 26, 2024. The contents of this application is incorporated by reference in its entirety.

### TECHNICAL FIELD

The present description relates generally to electronic devices. More specifically, the present description relates to switches based on a phase-change material capable of alternating between an electrically conductive crystalline phase and an amorphous, electrically insulating phase.

### BACKGROUND ART

Various applications take advantage of switches based on a phase-change material to enable or prevent the flow of an electric current in a circuit. In particular, such switches can be used in radio-frequency communication applications, for example to switch an antenna between transmit and receive modes, to activate a filter corresponding to a frequency band, etc.

However, existing switches based on phase-change material have various drawbacks.

### SUMMARY OF INVENTION

It would be desirable to overcome some or all of the disadvantages of existing switches based on a phase-change material.

To this end, one embodiment provides a switch based on a phase-change material comprising:
a region of said phase-change material coupling first and second conduction electrodes of the switch;
a waveguide located vertically in line with the region of said phase-change material and comprising a central region of a first material having a first refractive index surrounded by a peripheral region of a second material having a second refractive index lower than the first refractive index; and
a region of a third material having a third refractive index lower than the second refractive index and located in the peripheral region of the waveguide vertically in line with a first face of the central region of the waveguide opposite the region of said phase-change material.

In one embodiment, the region of said third material extends from the first face of the central region of the waveguide.

According to one embodiment, the region of said third material is a cavity at least partially filled with one or more solid, liquid or gaseous substances, preferably an air-filled cavity.

According to one embodiment, the region made of said third material has, when viewed from above, a tapered shape flaring out along a direction of propagation of an optical signal for controlling the switch.

According to one embodiment, the region made of said phase-change material has a width of the order of one or more tens of micrometers, preferably between 10 and 100 μm, more preferably between 30 and 100 μm.

According to one embodiment, a second face of the central region of the waveguide, opposite the first face, is separated from the region of said phase-change material by a distance of between 0 and 550 nm.

According to one embodiment, the central region of the waveguide has:
a width of between 200 nm and 2 μm; and
a height of between 200 and 400 nm.

According to one embodiment, the first and second conduction electrodes form part of an antenna element of a transmitarray or reflectarray cell.

According to one embodiment, the central region of the waveguide is interposed between the first and second conduction electrodes, on the one hand, and the region of said phase-change material, on the other hand.

According to one embodiment, the region of said phase-change material is interposed between the first and second conduction electrodes, on the one hand, and the central region of the waveguide, on the other hand.

According to one embodiment, said phase-change material is:
a chalcogenide material, preferably germanium telluride, antimony telluride or germanium-antimony-telluride; or
vanadium dioxide.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1A and FIG. 1B are schematic and partial views, respectively from above and in cross-section along plane BB of FIG. 1A, illustrating an example of a switch based on a phase-change material;

FIG. 2A and FIG. 2B are schematic and partial views, respectively from above and in cross-section along the plane BB of FIG. 2A, illustrating an example of a switch based on a phase-change material according to one embodiment; and

FIG. 3 is a graph illustrating variations in the optical power absorbed by a region of phase-change material of the switch of FIGS. 2A and 2B along a direction of propagation, in a waveguide, of an optical signal for actuating the switch.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the control circuits for switches based on a phase-change material and the applications in which such switches can be provided have not been detailed, the embodiments and variants described being compatible with the control circuits for switches based on a phase-change material and with the usual applications involving switches based on a phase-change material.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10% or 10°, and preferably within 5% or 5°.

In the following description, “insulating” and “conductive” mean electrically insulating and electrically conductive, respectively, unless otherwise specified.

Unless otherwise specified, “in contact with” means “in mechanical contact with”.

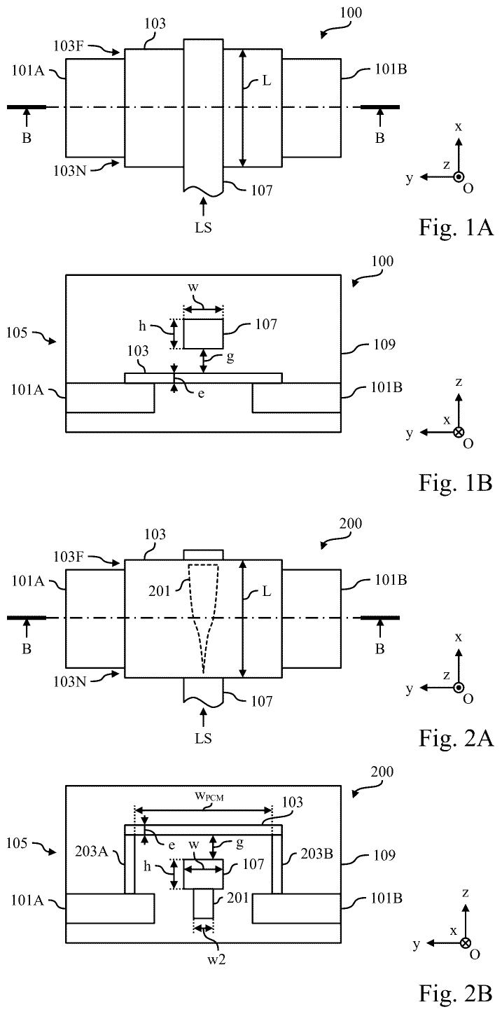

FIG. 1A and FIG. 1B are schematic and partial views, respectively from above and in cross-section along plane BB of FIG. 1A, illustrating an example of a switch 100 based on a phase-change material. In the example shown, plane BB in FIG. 1A is a vertical plane parallel to a conduction direction of switch 100.

In FIGS. 1A and 1B, the conduction direction of switch 100 is parallel to a horizontal axis Oy, and plane BB is parallel to a vertical plane Oyz orthogonal to an axis Ox.

In the example shown, switch 100 comprises conduction electrodes 101A and 101B. The conduction electrodes 101A and 101B of switch 100 are, for example, intended to be connected to a radio-frequency communication circuit, not detailed in the figures. The conduction electrodes 101A and 101B are made of an electrically conductive material, for example a metal, such as copper or aluminum, or a metal alloy. Furthermore, the conduction electrodes 101A and 101B may have a single-layer or multi-layer structure.

Although not detailed in FIGS. 1A and 1B so as not to overload the drawing, the conduction electrodes 101A and 101B of switch 100 are for example located on and in contact with an upper face of an electrically insulating layer, for example of silicon dioxide (SiO₂), coating a substrate. By way of example, the substrate in this case is a wafer or a piece of wafer made of a semiconductor material, e.g. silicon. The conduction electrodes 101A and 101B of the switch 100 are, for example, part of an antenna element of a transmitarray or reflectarray cell.

In the illustrated example, the switch 100 further comprises a region 103 of phase-change material coupling the conduction electrodes 101A and 101B. Although not detailed in the figures, the region 103 of phase-change material, for example, coats an upper face of a further electrically insulating layer, for example of silicon dioxide, extending laterally between the electrodes 101A and 101B, the electrically insulating layer being for example flush with the upper faces of the electrodes 101A and 101B. In the example shown, the region 103 of phase-change material extends over and contacts part of the top face of each conduction electrode 101A, 101B. In the example shown, the region 103 of phase-change material has a width L. More precisely, the width L of region 103 corresponds to the lateral dimension of region 103 measured along the Ox axis. The width L of the region 103 of phase-change material is, for example, of the order of a few tens of micrometers, for example between 10 and 100 μm, for example between 30 and 100 μm. By way of example, the region 103 of phase-change material has a thickness e of the order of 100 nm.

For example, region 103 of switch 100 is made of a “chalcogenide” material, i.e. a material or alloy comprising at least one chalcogen element, e.g. a material of the germanium telluride (GeTe), antimony telluride (SbTe) or germanium-antimony-telluride (GeSbTe, commonly known by the acronym “GST”) family. Alternatively, region 103 is made of vanadium dioxide (VO₂).

Generally speaking, phase-change materials are materials capable of alternating, under the effect of a temperature variation, between a crystalline phase and an amorphous phase, the amorphous phase having a higher electrical resistance than the crystalline phase. In the case of switch 100, this phenomenon is exploited to obtain a blocked state, preventing current flow between conduction electrodes 101A and 101B, when the material of region 103 located between the conduction electrodes is in the amorphous phase, and a conducting state, allowing current flow between conduction electrodes 101A and 101B, when the material of region 103 is in the crystalline phase.

In the example shown, the switch 100 further comprises a waveguide 105 located opposite the region 103 of phase-change material and extending laterally along a main direction substantially orthogonal to the conduction direction of the switch 100. In FIGS. 1A and 1B, the waveguide 105 of the switch 100 extends parallel to the Ox axis. The waveguide 105 has, for example, a first end facing an upper face of the phase-change material region 103 and a second end, opposite the first end, intended to be illuminated by a laser source LS. The laser source LS, for example, emits radiation constituting an optical control signal for the switch 100. The laser radiation LS emitted by the source propagates in waveguide 105, for example, in the form of an optical wave. By way of example, the radiation emitted by the LS laser source has a magnetic transverse polarization (TM) or an electrical transverse polarization (TE).

In the illustrated example, waveguide 105 comprises a central region 107, or core, surrounded by an electrically insulating peripheral region 109. In the illustrated example, the central region 107 of waveguide 105 extends parallel to the Ox axis. The central region 107 and the peripheral region 109 of the waveguide 105 are made of materials chosen to achieve a refractive index contrast that enables an optical mode of interest emitted by the laser source LS to be confined and guided. For example, the material of the central region 107 of waveguide 105 has a refractive index strictly higher than that of the peripheral region 109. For example, the central region 107 of waveguide 105 is made of silicon nitride and the peripheral region 109 is made of silicon dioxide.

Plane BB in FIG. 1A is substantially orthogonal to a propagation direction of the laser radiation in waveguide 105. The direction of propagation of laser radiation in waveguide 105 is, in the example shown, parallel to the Ox axis. In the example shown, the peripheral region 109 of the waveguide 105 covers the faces of the central region 107 parallel to the direction of propagation of the laser radiation (the lateral, lower and upper faces of the central region 107 of the waveguide 105 parallel to the Ox axis, in FIGS. 1A and 1B). More precisely, the peripheral region 109 is in contact with the lateral, lower and upper faces of the central region 107. In this example, part of the peripheral region 109 of the waveguide 105 extends vertically, along the vertical axis Oz orthogonal to the horizontal axes Ox and Oy, from a face of the central region 107 located opposite the region 103 made of phase-change material (the lower face of the central region 107 of the waveguide 105, in the orientation of FIG. 1B) to a face of the phase-change material region 103 opposite the conduction electrodes 101A and 101B (the upper face of the phase-change material region 103, in the orientation of FIG. 1B).

In the example shown, the central region 107 has a substantially rectangular cross-section when viewed in cross-section along plane BB orthogonal to the direction of laser radiation propagation in waveguide 105. By way of example, the central region 107 has a width w (along the Ox axis) equal to approximately 300 nm and a height h (along the Oz axis) equal to approximately 350 nm, as seen in cross-section along plane BB. Furthermore, the central region 107 of the waveguide 105 is separated from the phase-change material region 103 by a distance g. In this example, the distance g is equivalent to a thickness of the part of the peripheral region 109 interposed between the central region 107 of the waveguide 105 and the region 103 of phase-change material. By way of example, the distance g is equal to approximately 300 nm.

Waveguide 105 is, for example, of the single-mode type, i.e. it is adapted to confine and guide a single optical mode for each type of polarization. For example, waveguide 105 is more precisely adapted to confine and guide a single optical mode chosen from a zero-order transverse electric mode (TE0), parallel to the Oy axis, and a zero-order transverse magnetic mode (TM0), parallel to the Oz axis. Since the TE0 and TM0 modes are orthogonal, they cannot couple to each other in waveguide 105. The choice of the mode confined and guided by waveguide 105, between the TE0 and TM0 modes, is determined by the polarization of the laser source LS. Thus, in a case where the laser source LS emits radiation with a transverse magnetic polarization TM, waveguide 105 is adapted to confine and guide the zero-order transverse magnetic mode TM0 only.

On the side of its end intended to be illuminated by the laser source LS, waveguide 105 comprises, for example, an input coupling element, also known as the waveguide 105 input surface. On the side of its end facing the phase-change material region 103, the waveguide 105 may further comprise an output coupling element, also referred to as the output surface of the waveguide 105. The input coupling element may have a structure, such as a diffraction grating with a Bragg structure or any other coupling structure, for capturing the radiation emitted by the laser source LS and propagating this radiation to the output surface.

Alternatively, the output surface of waveguide 105 may feature a structure for re-emitting radiation propagated from the input surface to the phase-change material region 103. Although not detailed in FIGS. 1A and 1B, the output surface of waveguide 105 may have a structure identical or similar to that of its input surface.

Generally speaking, in the example shown, the input and output surfaces of waveguide 105 respectively receive and transmit radiation, or an optical wave, in a direction orthogonal to the direction of propagation of the radiation, or optical wave, inside waveguide 105, for example a direction parallel to the Oz axis. Alternatively, at least one of the input and output surfaces of waveguide 105 may have a structure that enables it to receive or transmit radiation, or an optical wave, respectively, in a direction parallel to the direction of propagation of the radiation, or optical wave, within waveguide 105 (parallel to the Ox axis, in this example).

To switch the switch 100 from the off state to the on state, the region 103 is heated by the laser source LS, via the waveguide 105, to a temperature T1 and for a time d1. The temperature T1 and duration d1 are chosen so as to bring about a phase change in the material of region 103 from amorphous to crystalline phase. For example, temperature T1 is above a crystallization temperature and below a melting temperature of the phase-change material, and duration d1 is between 10 and 100 ns.

Conversely, to switch the switch 100 from the on state to the off state, the region 103 is heated by the laser source LS, via the waveguide 105, to a temperature T2, higher than the temperature T1, and for a time d2, shorter than the time d1. The temperature T2 and duration d2 are chosen so as to cause a phase change of the material in the region 103 from crystalline to amorphous. For example, temperature T2 is higher than the melting temperature of the phase-change material, and duration d2 is of the order of 10 ns.

A disadvantage of switch 100 is that the optical wave propagating in waveguide 107 is not homogeneously absorbed in the region 103 of phase-change material along the direction of propagation of the optical wave in waveguide 105 (along the Ox axis, in this example). In the example of switch 100, the optical wave is predominantly absorbed by a first portion 103N of the phase-change material region 103 close to the laser source LS, the optical wave absorption being weaker in a second portion 103F of the phase-change material region 103, opposite the first portion 103N, further from the laser source LS than the portion 103N. More precisely, the optical absorption of the wave by the phase-change material region 103 follows a decreasing exponential from part 103N of region 103 to part 103F.

Thus, during an activation phase of switch 100, the optical power absorbed by the second part 103F of region 103 may be insufficient to cause a phase change of the material in part 103F. If it is desired to switch the switch 100 from the on state to the off state, this may prevent the second part 103F of the region 103 from changing phase from crystalline to amorphous, thus undesirably allowing a leakage current to flow between the conduction electrodes 101A and 101B of the switch 100. This phenomenon is all the more likely to occur the greater the width L of the region 103.

The inventors realized that the phenomenon stems from the fact that the transverse magnetic mode TM of the laser signal activating the switch 100 confined and guided by the waveguide 105 is strongly absorbed by the phase-change material of the region 103, thus leading to much greater heating of the part 103N than that observed in the part 103F. To alleviate this problem, the geometry of waveguide 105 could be modified to confine and guide only the transverse electric mode TE, which is more weakly absorbed by the phase-change material of region 103 than the transverse magnetic mode TM. For example, the TM transverse magnetic mode has losses, due to absorption by the phase-change material in region 103, of the order of 2,500 dB·cm⁻¹, compared with around 500 dB·cm⁻¹ for the TE transverse electrical mode. However, for equivalent laser power values, this would not result in sufficient heating of region 103 to bring about phase change. More generally, in both transverse electric TE and transverse magnetic TM modes, optical absorption follows a law of the decreasing exponential type for this guide configuration. However, it would be preferable for the absorption to follow a linear law to enable the state of the phase-change material in region 103 to be modified.

On the other hand, switches based on a phase-change material with so-called “direct” optical actuation have been proposed. In such switches, the phase-change material region is, for example, irradiated by a laser source focused on said region, the switches being, for example, devoid of a waveguide between the laser source and the phase-change material region.

Such a switch is described in the article by A. Crunteanu et al. entitled “Optical Switching of GeTe Phase Change Materials for High-Frequency Applications” and published in 2017 following the “IEEE MTT-S International Microwave Workshop Series on Advanced Materials and Processes for RF and THz Applications (IMWS-AMP)” conference. In this paper, a laser source based on krypton fluoride (KrF) emits radiation having a wavelength equal to about 248 nm, for example in the form of pulses, to cause transitions of a phase-change material region of a switch between amorphous and crystalline phases. A pulse with a fluence of the order of 90 mJ·cm⁻² is used, for example, to bring about a transition from the amorphous to the crystalline phase. In addition, a further pulse with a fluence of the order of 185 mJ·cm⁻² is used, for example, to achieve a transition from the crystalline to the amorphous phase.

Switches based on a phase-change material with direct optical actuation do have their drawbacks, however. In particular, they are incompatible with encapsulated component structures. In addition, each switch requires a dedicated laser source. This prevents or greatly complicates the realization of integrated electronic components comprising several individually controllable switches.

FIG. 2A and FIG. 2B are schematic and partial views, respectively from above and in cross-section along plane BB of FIG. 2A, illustrating an example of a switch 200 based on a phase-change material according to one embodiment.

The switch 200 shown in FIGS. 2A and 2B has elements in common with the switch 100 shown in FIGS. 1A and 1B. These common elements will not be detailed again below. The switch 200 of FIGS. 2A and 2B differs from the switch 100 of FIGS. 1A and 1B in that the switch 200 further comprises a region 201 located in the peripheral region 109 of the waveguide 105, plumb with a face of the central region 107 of the waveguide 105 opposite the region 103 made of phase-change material.

Furthermore, the central region 107 of the waveguide 105 of the switch 200 is vertically interposed between the conduction electrodes 101A and 101B, on the one hand, and the region 103 of phase-change material, on the other. However, this example is not limitative. Alternatively, the switch 200 may have a structure similar to that of the switch 100, in which the region 103 of phase-change material is interposed vertically between the conduction electrodes 101A and 101B, on the one hand, and the central region 107 of the waveguide 105, on the other. In this variant, the central region 107 of waveguide 105 is vertically interposed between region 103 of phase-change material and region 201.

In the example shown, the phase-change material region 103 is coupled to the conduction electrodes 101A and 101B by conductive vias 203A and 203B, respectively. In the orientation of FIG. 2B, vias 203A and 203B extend from the top faces of conduction electrodes 101A and 101B, respectively, to two opposite areas of the underside of phase-change material region 103. The vias 203A and 203B are separated by a distance w_{PCM} corresponding, for example, to a width of a so-called “active” zone of the region 103 of phase-change material, i.e. a zone of the region 103 in which the phase change actually occurs when the optical signal controlling the switch 200 is transmitted via the waveguide 105.

In the example shown, region 201 extends into the peripheral region 109 of waveguide 105 from the side of central region 107 opposite region 103. In the orientation of FIG. 2B, the central region 107 of waveguide 105 is located on and in contact with the top face of region 201. In the illustrated example, the peripheral region 109 of waveguide 105 covers all faces of region 201 except its top face. More precisely, the peripheral region 109 is in contact with all the faces of the region 201 with the exception of its top face.

Furthermore, in this example, the peripheral region 109 of the waveguide 105 covers the faces of the central region 107 parallel to the direction of propagation of the optical control signal of the switch 200 (the lateral, lower and upper faces of the central region 107 of the waveguide 105 parallel to the axis Ox, in FIGS. 2A and 2B) with the exception of at least part of its lower face located in contact with the region 201. In the example shown, region 109 is more precisely in contact with said faces of region 107.

However, this example is not limitative and region 201 can, alternatively, be separated from central region 107 of waveguide 105 by a portion of peripheral region 109 extending vertically, along the Oz axis, from a face of central region 107 facing region 201 (the lower face of central region 107, in the orientation of FIG. 2B) to a face of region 201 facing central region 107 (the upper face of region 201, in the orientation of FIG. 2B). In this variant, the peripheral region 109 of the waveguide 105 covers, or more precisely is in contact with, all the faces of the region 201 and the lateral, lower and upper faces of the central region 107 of the waveguide 105 parallel to the Ox axis.

In one embodiment, region 201 is made of a material with a refractive index strictly lower than that of the peripheral region 109 of waveguide 105. The region 201 is, for example, a cavity formed in the peripheral region 109 of the waveguide 105. Generally speaking, the cavity is at least partially filled with one or more solid, liquid or gaseous substances having a refractive index lower than that of the peripheral region 109 of the waveguide 105. For example, the cavity is at least partially filled with at least one substance chosen from:
a gas, e.g. carbon dioxide, or a gas mixture, e.g. air;
a liquid, e.g. acetone; and/or
ice.

The presence of the region 201 with a lower refractive index than the peripheral region 109 of the waveguide 105 increases the absorption of the optical control signal of the switch 200 by the phase-change material of the region 103. The greater the width w2 (along the Ox axis) of region 201, the greater the absorption of the optical control signal of switch 200 by the phase-change material of region 103. In the example shown, when viewed from above, the region 201 has a tapered shape flaring out, i.e. widening, along the direction of propagation of the optical control signal for the switch 200. More precisely, in this example, the width w2 of the region 201 is smaller in the vicinity of the part 103N of the region 103 than in the vicinity of the part 103F. In the example shown, the width w2 of region 201 increases monotonically from part 103N to part 103F.

The table below provides examples of minimum (min) and maximum (max) values, in nanometers (nm), of various dimensions of the switch 200, in this case: the height h and width w of the central region 107 of the waveguide 105, the distance g separating the central region 107 of the waveguide 105 from the region 103 made of phase-change material, and the width w2 of the region 201.

TABLE 1

| Dimension | Min value (nm) | Max value (nm) |
|---|---|---|
| h | 200 | 400 |
| w | 200 | 2,000 |
| g | 0 | 550 |
| w2 | 0 | W_{PCM} |

The value of the height h is chosen, for example, to enable a single transverse magnetic mode TM, for example the TM0 mode, to be guided without producing harmonics. The value of the width w is chosen, for example, so as to guide the optical control signal of the switch 200 without exciting higher-order modes. The value of the distance g, which separates the region 103 made of phase-change material from a face of the central region 107 of the waveguide 105 opposite the region 201, is chosen, for example, so as to enable an initial absorption level to be adjusted, i.e. in the vicinity of the part 103N of the region 103, in the absence of the region 201. The values of the width w2, for example, are chosen to control the position of the optical propagation mode.

The table below shows, by way of example, values for the width w2 of region 201 as a function of position along the Ox axis, with coordinate 0 corresponding to the position of the side face of region 103 on the 103N side. In the example below, the dimensions h, w, g and L are respectively equal to approximately 300 nm, 600 nm, 330 nm and 20 μm.

TABLE 2

| Position (μm) | w2 (μm) |
|---|---|
| 0 | 0 |
| 5 | 0.2 |
| 10 | 0.5 |
| >12 | 1 |

The table below shows, by way of example, values for the width w2 of region 201 as a function of position along the Ox axis. In the example below, the dimensions h, w, g and L are equal to approximately 400 nm, 200 nm, 350 nm and 30 μm respectively.

TABLE 3

| Position (μm) | w2 (μm) |
|---|---|
| 0 | 0 |
| 6 | 0.1 |
| 9.7 | 0.2 |
| 13 | 0.5 |
| >14 | 2 |

The table below shows, by way of example, values for the width w2 of region 201 as a function of position along the Ox axis. In the example below, the dimensions h, w, g and L are equal to approximately 200 nm, 2 μm, 550 nm and 90 μm respectively.

TABLE 4

| Position (μm) | w2 (μm) |
|---|---|
| 0 | 0 |
| 11 | 0.1 |
| 16 | 0.2 |
| 20 | 0.3 |
| 43 | 1 |
| 52 | 1.2 |
| >69 | 3 |

In the above examples, the thickness e of the phase-change material region 103 is approximately 100 nm.

The examples given above are not, however, limitative, and the person skilled in the art is able to define the values of the dimensions h, w, g and w2 as a function of, among other things, the width L of the region 103 of phase-change material. Numerical simulation tools can be used for this purpose, for example.

An advantage of the switch 200 described above in relation to FIGS. 2A and 2B is that the presence of the region 201 ensures that the laser signal driving the switch 200 is absorbed substantially uniformly by the phase-change material of the region 103. More specifically, in the case of switch 200, the transverse magnetic mode TM is absorbed more weakly in the vicinity of the 103N part of the 103 region and more strongly in the vicinity of the 103F part of the 103 region. By way of example, TM mode losses are equal to around 500 dB·cm⁻¹ in the vicinity of the 103N part and equal to around 2,500 dB·cm⁻¹ in the vicinity of the 103F part. Compared with the switch 100 of FIGS. 1A and 1B, this avoids the situation where part of the region 103 made of phase-change material, for example the part 103F furthest from the laser source LS, does not change phase when the switch is controlled.

Integration of the switch 200 described above is particularly advantageous, for example, in electronic radio-frequency communication devices. Indeed, for this type of application, it is very interesting to have switches with a large width L, for example of the order of a few tens of micrometers, insofar as this limits the appearance of parasitic capacitance phenomena and enables more intense electrical signals to be switched than in the case of switches with a smaller width L. However, this example is not limitative, and the person skilled in the art can of course take advantage of the benefits of switch 200 in many applications other than radio-frequency communication applications.

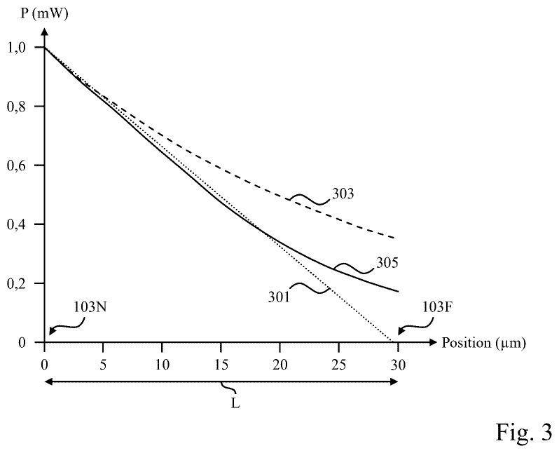

FIG. 3 is a graph illustrating variations in optical power P (in milliwatts, mW) absorbed by the phase-change material region 103 of switch 200 as a function of position (in micrometers, μm) measured along the Ox direction of propagation, in waveguide 105, of the optical signal actuating switch 200.

In the example shown, a curve 301 illustrates an ideal case in which optical power P is absorbed linearly in the phase-change material of region 103. This case leads to uniform, or homogeneous, heating of the phase-change material in region 103.

In FIG. 3, another curve 303 illustrates a case of a switch analogous to switch 200 but without the region 201. In this case, the distance g allows the phase-change material region 103 to absorb, in the first few micrometers from part 103N, optical power substantially equal to that absorbed in the ideal case illustrated by curve 301. However, in the last few micrometers in the vicinity of part 103F, the optical power absorbed is greater than that in the ideal case illustrated by curve 301. This is undesirable, as the phase-change material in region 103 risks being damaged by this excess optical power.

In the example shown, another curve 305 illustrates the case of switch 200, in which the distance g is substantially equal to that of the switch in the case of curve 303, and in which the presence of region 201 makes it possible to obtain, in region 103 made of phase-change material, an optical power absorption profile P very close to that of the ideal case illustrated by curve 301. Curve 305 corresponds more precisely to the example described above in relation to Table 3.

Various embodiments and variants have been described. The person skilled in the art will understand that certain features of these various embodiments and variants could be combined, and other variants will become apparent to the person skilled in the art. In particular, the dimensions e and L of the region 103 made of phase-change material, the dimensions w and h of the central region 107 of the waveguide 105, the dimension w2 of the region 201 and the distance g can be adapted by the person skilled in the art to from the indications of the present description, for example depending on the intended application.

Finally, the practical implementation of the embodiments and variants described is within the capabilities of the person skilled in the art from the functional indications given above. In particular, the embodiments described are not limited to the particular examples of materials and dimensions mentioned in the present description.

1. A switch based on a phase-change material comprising:
a region of said phase-change material coupling first and second conduction electrodes of the switch;
a waveguide located vertically in line with the region of said phase-change material and comprising a central region of a first material having a first refractive index surrounded by a peripheral region of a second material having a second refractive index lower than the first refractive index, the waveguide being adapted to transmit an optical control signal of the switch; and
a region of a third material having a third refractive index lower than the second refractive index and located in the peripheral region of the waveguide vertically in line with a first face of the central region of the waveguide opposite the region of said phase-change material.

2. A switch according to claim 1, wherein the region of said third material extends from the first face of the central region of the waveguide.

3. A switch according to claim 1, wherein the region of said third material is a cavity at least partially filled with one or more solid, liquid or gaseous substances, preferably an air-filled cavity.

4. A switch according to claim 1, wherein the region made of said third material has, when viewed from above, a tapered shape flaring out along a direction of propagation of an optical signal for controlling the switch.

5. A switch according to claim 1, wherein the region of said phase-change material has a width of the order of one or more tens of micrometers, preferably between 10 and 100 μm, more preferably between 30 and 100 μm.

6. Switch according to claim 1, wherein a second face of the central region of the waveguide, opposite the first face, is separated from the region of said phase-change material by a distance of between 0 and 550 nm.

7. A switch according to claim 1, wherein the central region of the waveguide has:
a width of between 200 nm and 2 μm; and
a height of between 200 and 400 nm.

8. A switch according to claim 1, wherein the first and second conduction electrodes form part of an antenna element of a transmitarray or reflectarray cell.

9. A switch according to claim 1, wherein the central region of the waveguide is interposed between the first and second conduction electrodes, on the one hand, and the region of said phase-change material, on the other hand.

10. A switch according to claim 1, wherein the region of said phase-change material is interposed between the first and second conduction electrodes, on the one hand, and the central region of the waveguide, on the other hand.

11. A switch according to claim 1, wherein said phase-change material is:
a chalcogenide material, preferably germanium telluride, antimony telluride or germanium-antimony-telluride; or
vanadium dioxide.
